(19) United States
(12) Patent Application Publication
(10) Pub. No.: US 2013/0179741 A1
(43) Pub. Date: Jul. 11, 2013

(54) MAPPING CIRCUIT TEST LOGIC BY ANALYZING REGISTER TRANSFER LEVEL CIRCUIT MODELS

(71) Applicant: Joshua P. Sinykin, Shrewsbury, MA (US)

(72) Inventor: Joshua P. Sinykin, Shrewsbury, MA (US)

(73) Assignee: LSI CORPORATION, Milpitas, CA (US)

(21) Appl. No.: 13/344,851

(22) Filed: Jan. 6, 2012

(51) Int. Cl. G01R 31/3177; G06F 11/25

(52) U.S. Cl. 714/724; 714/E11.155

(57) ABSTRACT

Methods and systems for mapping and programming the debug logic of a circuit are provided. The system acquires a Register Transfer Level (RTL) representation of a circuit, wherein the circuit implements test logic that is externally programmable for providing one or more output signals corresponding to internal operational signals. The system analyzes the RTL representation to identify test multiplexers (MUXs) having registers for implementing the test logic, and correlates test register values for the test MUXs with outputs corresponding to the internal operational signals, based upon the RTL representation. The system further enables a user to select a desired internal operational signal for acquisition. Additionally, the system programs the test registers of the test MUXs of the circuit based on the correlated test register values to acquire the selected internal operational signal and to apply the acquired signal as one or more output signals.

### BACKGROUND

1. Field of the Invention

The invention relates generally to circuit design/testing, and more specifically relates to acquiring internal signals of a circuit by analyzing the circuit's design and programming test logic of the circuit to output desired internal signals based upon the analysis.

3. Discussion of Related Art

Electronic circuits perform a wide variety of tasks for electronic systems. For example, circuits may be used for data processing, data storage and retrieval, system analysis and control, and many other functions. Because electronic circuits may be subject to programming, design, or operational errors, it is desirable not only to include logic at the circuit that performs the circuit's desired task, but also to include logic at the circuit for debugging and testing purposes (e.g., for externally monitoring internal operational signals of the circuit). For example, the circuit may include test multiplexers (MUXs) along with registers that can be programmed to provide internal operational signals as outputs (e.g., specialized debug outputs) for the circuit. Utilizing MUXs to output test signals that are normally internal to the circuit ensures that the number and size of communication channels used for debug and testing purposes at the circuit is reduced, because MUXs allow a large number of internal signaling pathways to be condensed into a much smaller number of output signal paths.

Unfortunately, utilizing a hierarchy of test MUXs to provide internal debug signals results in a number of problems. For example, the registers of the test MUX hierarchy must be properly programmed in order to acquire a desired input signal and provide it to an output signal pathway for external monitoring. For circuits utilizing a large number of test MUXs, this process may be particularly complex as a user traces the desired signal's path across the test MUX hierarchy to an output for the circuit. As such, it is not uncommon for a test MUX hierarchy to be improperly programmed based upon user error. Furthermore, external documentation relied upon for programming registers for test MUXs of a given circuit may be out of date because the circuit design has been updated or altered since the documentation was prepared. If this is the case, the information describing how to program registers for the test MUXs may be inaccurate. This in turn further complicates the task of acquiring internal operational signals of the circuit.

Thus it is an ongoing challenge to map internal operational signals of an electronic circuit for output via test MUXs in a manner that is both convenient and effective.

### SUMMARY

The present invention solves the above and other problems, thereby advancing the state of the useful arts, by providing methods and systems for analyzing Register Transfer Level (RTL) representations of an electronic circuit in order to correlate register values used for programming test multiplexers (MUXs) with outputs corresponding to internal operational signals of a circuit. An RTL representation of a circuit is a digital representation of a circuit design, often utilized in Computer Aided Design (CAD) applications. Because RTL representations are an integral part of the design process for most circuits, they are typically reliably up-to-date (e.g., redesigning the circuit typically starts with redesigning the RTL representation of the circuit). Analysis of an RTL representation of a circuit allows a testing system to correlate test MUXs with internal operational signals (and to program registers of those test MUXs as well) without a danger of user error.

In one aspect hereof, a method operable as programmed instructions on a computer system is provided. The method comprises acquiring a Register Transfer Level (RTL) representation of an electronic circuit, the circuit implementing operational logic for performing tasks, the circuit further implementing test logic that may be externally programmed for providing one or more output signals corresponding to internal operational signals. The method further comprises analyzing the RTL representation to identify test multiplexers (MUXs) having registers for implementing the test logic, and correlating test register values for the test MUXs with outputs corresponding to the internal operational signals, based upon the RTL representation. Additionally, the method comprises selecting a desired internal operational signal for acquisition, and programming the test registers of the test MUXs of the circuit based on the correlated test register values to acquire the selected internal operational signal and to apply the acquired signal as one or more output signals.

Another aspect hereof provides a non-transitory computer readable medium embodying programmed instructions which, when executed by a processor, are operable for performing a method. The method comprises acquiring a Register Transfer Level (RTL) representation of an electronic circuit, the circuit implementing operational logic for performing tasks, the circuit further implementing test logic that may be externally programmed for providing one or more output signals corresponding to internal operational signals. The method further comprises analyzing the RTL representation to identify test multiplexers (MUXs) having registers for implementing the test logic, and correlating test register values for the test MUXs with outputs corresponding to the internal operational signals, based upon the RTL representation. Additionally, the method comprises selecting a desired internal operational signal for acquisition, and programming the test registers of the test MUXs of the circuit based on the correlated test register values to acquire the selected internal operational signal and to apply the acquired signal as one or more output signals.

Another aspect hereof provides a circuit testing system. The circuit testing system comprises a control unit adapted to acquire a Register Transfer Level (RTL) representation of an electronic circuit, the circuit implementing operational logic for performing tasks, the circuit further implementing test logic that is externally programmable for providing one or more output signals corresponding to internal operational signals. The control unit is further adapted to analyze the RTL representation to identify test multiplexers (MUXs) having registers for implementing the test logic, and adapted to correlate test register values for the test MUXs with outputs corresponding to the internal operational signals, based upon the RTL representation. The circuit testing system also comprises a user interface adapted to enable a user to select a desired internal operational signal for acquisition. Additionally, the circuit testing system comprises a circuit interface adapted to program the test registers of the test MUXs of the circuit based on the correlated test register values to acquire the selected internal operational signal and to apply the acquired signal as one or more output signals.

### BRIEF DESCRIPTION OF THE DRAWINGS

FIG. 1 is a block diagram of an exemplary test system for utilizing a Register Transfer Level (RTL) circuit model to correlate internal signals of a circuit with registers for test multiplexers (MUXs) in accordance with features and aspects hereof.

FIG. 2 is a flowchart describing an exemplary method in accordance with features and aspects hereof to correlate internal signals of a circuit with registers for test multiplexers (MUXs) based on a Register Transfer Level (RTL) circuit model of the circuit.

FIG. 3 is a flowchart describing exemplary further details of selecting internal signals of a circuit for acquisition in accordance with features and aspects hereof.

FIG. 4 is a block diagram of an exemplary electronic circuit in accordance with features and aspects hereof.

FIG. 5 is a block diagram of an exemplary test MUX mapping structure for a circuit in accordance with features and aspects hereof.

FIG. 6 is a block diagram of another exemplary electronic circuit in accordance with features and aspects hereof.

FIG. 7 is a block diagram of exemplary data structures indicating whether internal operational signals of a circuit are padded with non-informational content in accordance with features and aspects hereof.

### DETAILED DESCRIPTION OF THE DRAWINGS

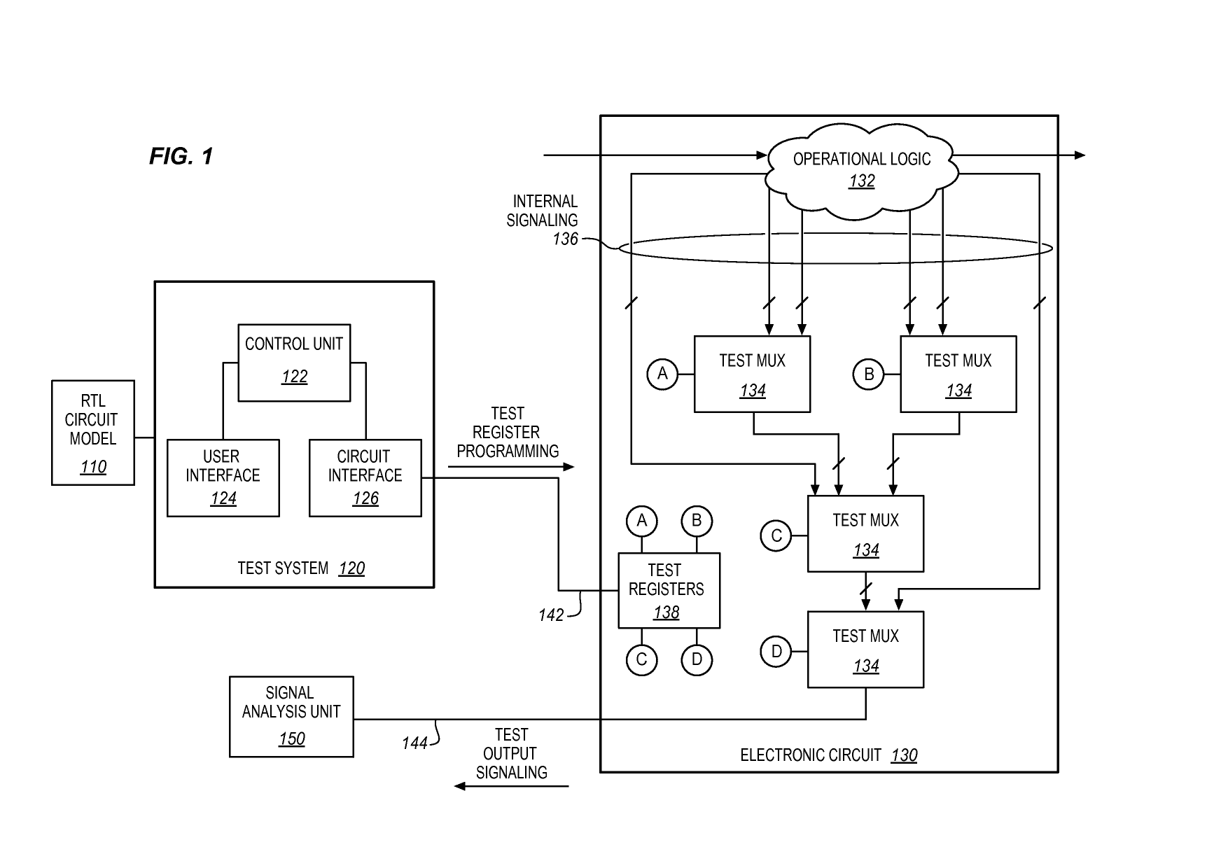

FIG. 1 is a block diagram of an exemplary test system 120 for utilizing a Register Transfer Level (RTL) circuit model 110 to correlate internal signals of an electronic circuit 130 with registers for test multiplexers (MUXs) in accordance with features and aspects hereof.

According to FIG. 1, electronic circuit 130 includes electronic components capable of implementing operational logic 132 for performing a task. For example, operational logic 132 may include logic for processing, performing data storage and retrieval, actuating an electronic component, etc. It will be understood that operational logic 132 therefore comprises the logic components for performing the primary functions of circuit 130. In addition to operational logic 132, circuit 130 includes a variety of test MUXs 134 for providing internal operational signals 136 (e.g., signals used for the primary functions of circuit 130) to test output(s) 144. Using MUXs, a large number of internal operational signals 136 may be routed to a smaller number of test output(s) 144 of circuit 130. Note also that operational logic 132 will generally include its own dedicated inputs and outputs for performing tasks which are separate from those used by the test/debug logic. The test output(s) 144 used by test MUXs 134 are therefore likely to exist as separate signaling pathways or buses (e.g., a dedicated debug output) distinct from those used by the operational logic at circuit 130.

Typically, test MUXs 134 will exist within a hierarchy of MUXs and registers. This hierarchy may be configured to select a variety of internal signals for application to test output(s) 144. The internal design and features of each test MUX 134 will naturally vary as a matter of design choice. For example, the internal selecting logic (i.e., the input and output paths of the MUX), the hardware registers, and the size and number of inputs and outputs all may vary across different designs of test MUXs 134. Test MUXs 134 may be coupled with each other via one or more buses, as indicated on FIG. 1. These buses may vary in size and number depending on the particular test MUXs 134 that they are coupled with. For example, a test MUX 134 may receive some signals along a two bit bus, may receive other signals along a four bit bus, and may transmit routed signals along an eight bit bus. Signals transmitted via test MUXs 134 may be padded with non-informational content or truncated as desired as they are routed through the MUX hierarchy.

Test MUXs 134 may be programmed via test registers 138 in order to provide the appropriate output signals (e.g., to other test MUXs 134 or to output(s) 144). According to FIG. 1, test registers 138 may be grouped into a single set of registers, or may be segmented into multiple sets of registers, wherein each set is accessible via a communication channel 142 for programming by an external source. When programmed, test registers 138 provide selection signaling used for configuring test MUXs 134 via communication channels indicated by A, B, C, and D of FIG. 1.

Register Transfer Level (RTL) circuit model 110 comprises a representation of the digital design of electronic circuit 130. For example, RTL circuit model 110 may be the basis for the design from which circuit 130 was fabricated. In some embodiments, the RTL may be structured in accordance with Verilog Hardware Description Language (Verilog HDL). In RTL, a circuit's behavior is defined by the flow of signals as they travel between hardware registers. RTL circuit model 110 may further define the logical operations that can be performed upon signals for the circuit by programming the registers. For example, RTL circuit model 110 may include RTL expressions and statements describing and labeling the various inputs and outputs of test MUXs 134. The RTL may define a number of further features of circuit 130. For example, RTL circuit model 110 may describe the size of each bus used by test MUXs 134, and may further indicate how signals are padded or truncated as they are transferred between buses of varying size. RTL circuit model 110 may be stored in a memory accessible by testing system 120. RTL circuit model 110 reliably represents the components of circuit 130, because unlike manually generated documentation which may fail to get updated, RTL circuit model 110 is an integral part of the design process of most circuits.

Test system 120 may be used to analyze RTL circuit model 110 in order to determine how to program registers for test MUXs 134 of circuit 130. In this embodiment, test system 120 comprises control unit 122, user interface 124, and circuit interface 126. Control unit 122 may comprise, for example, a general purpose (hardware) processor and associated memory for executing programmed instructions and managing the operations of test system 120. User interface 124 may comprise, for example, instructions for generating a display provided on a display device such as a monitor or screen. The display allows a user to interact with test system 120 and receive feedback from test system 120. Circuit interface 126 comprises any components, systems, or devices capable of identifying and programming test registers 138 for test MUXs 134 of circuit 130 via communication channel 142.

Communication channel 142 and output(s) 144 may comprise any suitable signaling pathways or buses. Communication channel 142 will typically utilize serialized communications to some degree in order to reduce its physical size and complexity. In contrast, output(s) 144 will typically output test signals on a parallel bus structure so that measured signals can be accurately provided essentially in real time.

Signal analysis unit 150 includes components for receiving test output signaling via output(s) 144. As test output signaling is received by signal analysis unit 150, the signaling may be applied to a logic analyzer or other electronic acquisition/analysis components. Such equipment utilizes the test output signals to aid an engineer in testing or debugging the design of circuit 130 during its operation. Signal analysis unit 150 may comprise an independent device or an integrated component of test system 120.

While in operation, test system 120 is capable of analyzing RTL circuit model 110 to correlate register values for test MUXs 134 of circuit 130 with internal operational signals of circuit 130. This analysis may be performed in the following manner: control unit 122 may parse the RTL to identify test MUXs 134 defined within the RTL (the MUXs and associated signal paths being identified by, for example, a naming convention or format adhered to in the design of circuit 130), as well as to identify test registers 138 defined for the test MUXs 134. For example, control lines (used to carry test register values to test MUXs 134) may include an RTL prefix with the keyword “TMuxSel,” and these control lines may further include a suffix that uniquely identifies the MUX that they are used to program. The test MUX may label inputs as “TMuxInUniqueName,” and outputs as “TMuxOutUniqueName” to indicate connectivity within the test logic hierarchy for circuit 130. Each input may relate to one or more named signals.

This information may then be stored in a database, such as an XML database, for later use and potential editing. The database may be used to trace the path of an individual internal operational signals across a hierarchy of test MUXs 134. Further, the database may be used to determine how to program test registers 138 of the hierarchy in order to direct the internal operational signal through test MUXs 134 towards output(s) 144 received by test system 120.

Once combinations of register values for test MUXs 134 have been determined to yield specific internal operational signals as signals along output(s) 144, a user may select one or more internal signals via user interface 124. A selected signal may, for example, be an input of a given test MUX 134 (e.g., the user may indicate their wish to view a signal as applied to a test MUX 134). With the appropriate internal signals selected for acquisition, control unit 122 may direct circuit interface 126 to program the test registers 138 for test MUXs 134 to acquire and provide the selected signals as signals along output(s) 144.

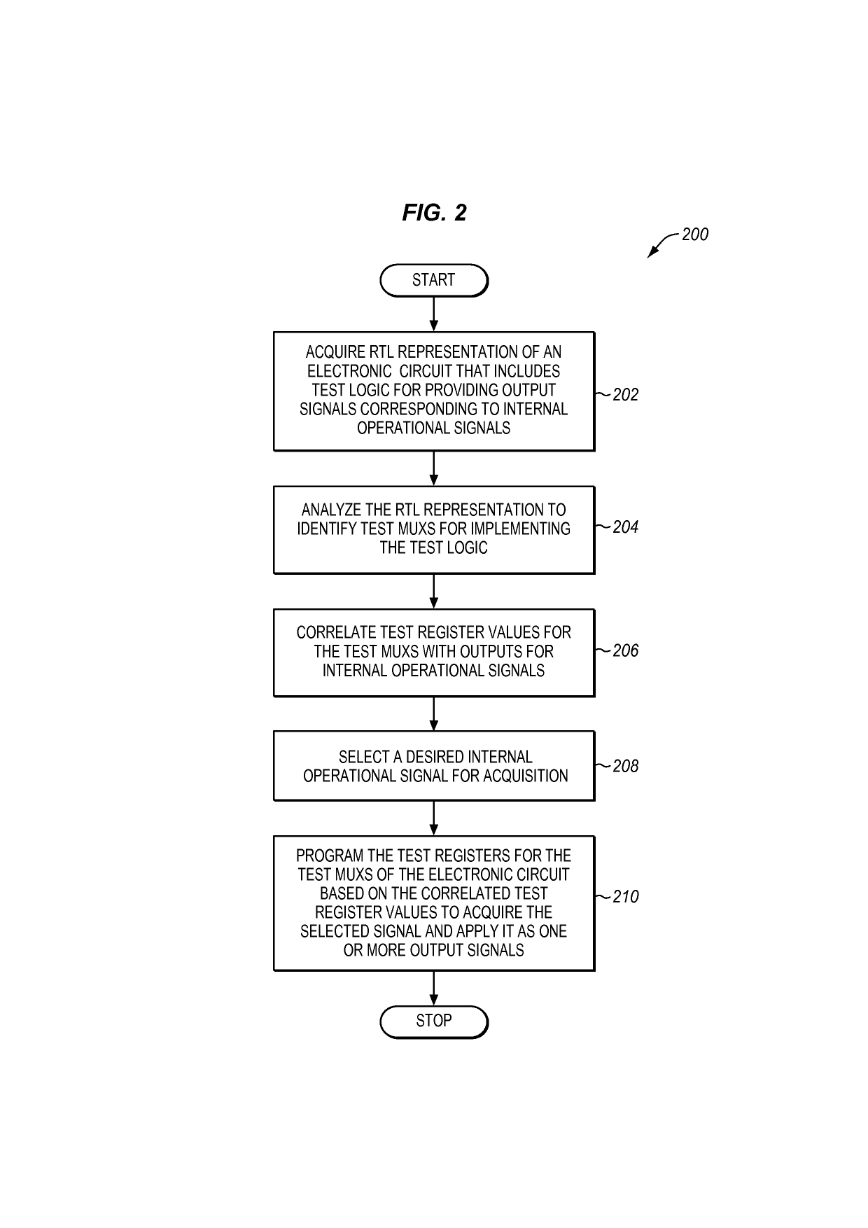

FIG. 2 is a flowchart describing an exemplary method 200 in accordance with features and aspects hereof to correlate internal signals of an application circuit with registers for test multiplexers (MUXs) based on a Register Transfer Level (RTL) representation of the circuit. The method of FIG. 2 may be operable in a test system such as described above with regard to FIG. 1, and may further be operable as programmed instructions on a computer system.

Step 202 includes acquiring an RTL representation of a circuit. The circuit includes operational logic for performing tasks, and further includes test logic that may be externally programmed for providing one or more output signals of the circuit corresponding to internal operational signals. The internal operational signals may be acquired, for example, for purposes of testing and analyzing the operation of the circuit. An RTL representation of the circuit may be acquired by querying a user via a user interface for information that includes the RTL representation. In one embodiment, output signals from the circuit indicate a name and version number from the circuit. With this information, a corresponding. RTL representation of the circuit may be found.

Step 204 includes analyzing the RTL representation to identify test multiplexers (MUXs) and associated registers for implementing the test logic. In the RTL representation, test MUXs may be distinguished from other circuit components based upon a tag, naming convention, or other identifier included in the RTL. For example, a tag may explicitly label each test MUX as such. In a further example, test MUXs may be identified in the RTL because they use a unique data structure (i.e., a particular standard cell that is used for test MUX functions). In a still further example, test MUXs may be distinguished from other MUXs because their input/output signals are indicated in the RTL as test/debug signals. Test MUXs may also be distinguished from other MUXs of the circuit by determining that the test MUXs are coupled with a communication channel used for testing/debugging purposes (the communication channel comprising a number of signals concatenated together using standard RTL syntax).

Step 206 includes correlating test register values for the test MUXs with outputs corresponding to the internal operational signals, based upon the RTL representation. For example, the method may review the RTL for test MUXs in order to track how their outputs align with inputs of other test MUXs. In such an example, an RTL parser may be used to follow connections from test MUX inputs to test MUX outputs. The RTL wires for the inputs/outputs eventually route to one or more exit wires of the design, and the hierarchy of test logic can be created based off those connections.

Thus, a hierarchy of test MUXs can be determined This hierarchy may be used to determine how the test MUXs of the circuit may be programmed to provide internal operational signals as output signals (i.e., an internal operational signal may be traced through the test MUX hierarchy to an output signal). As a combination of test register values is determined for providing internal operational signals as output signals, a record, database, or other mapping structure may be generated. The mapping structure may describe the test logic hierarchy, and may further specifically describe the appropriate register combinations to be used to acquire a given signal. For example, a mapping structure may be a database (e.g., an XML database) that indicates a name and associated value for each register used to provide a given operational signal at an output of the circuit. In further embodiments, step 206 may be included as a part of steps 204 and/or 208.

Step 208 includes selecting desired internal operational signal(s) for acquisition. The selection may be received from a user via a user interface, or may be acquired automatically based upon a predetermined testing scheme. According to step 208, one or more signals may be selected at the same time for output via circuit 130. If no mapping structure explicitly links a set of register combinations to acquiring a selected signal as an output, step 208 may include determining a path of test MUXs for the selected signals. For example, the path may be determined by reviewing a mapping structure describing the hierarchy of test logic. Beginning with the selected internal operational signals (represented as leaf nodes of the hierarchy of test logic) the method interrogates each level of the hierarchy to find matching information for test MUXs relating to selected signals. Test registers for the test MUX may be determined, and these test registers may be analyzed to determine which values will forward the selected signals onward towards an output.

Step 210 includes programming the test registers of the test MUXs of the circuit based on the correlated test register values to acquire the selected internal operational signal(s) from the test MUX hierarchy and to apply the acquired signal(s) as one or more output signals. A circuit interface or other element may be used to program the test registers.

Thus, using method 200 of FIG. 2, a model of the inner workings of the test logic of a circuit may be constructed. Furthermore, this model may be used by a testing system to automatically program the test logic of the circuit in order to acquire selected internal signals of the circuit. This in turn reduces the complexity of debugging and reduces the chances of user error when acquiring an internal operational signal for acquisition/monitoring.

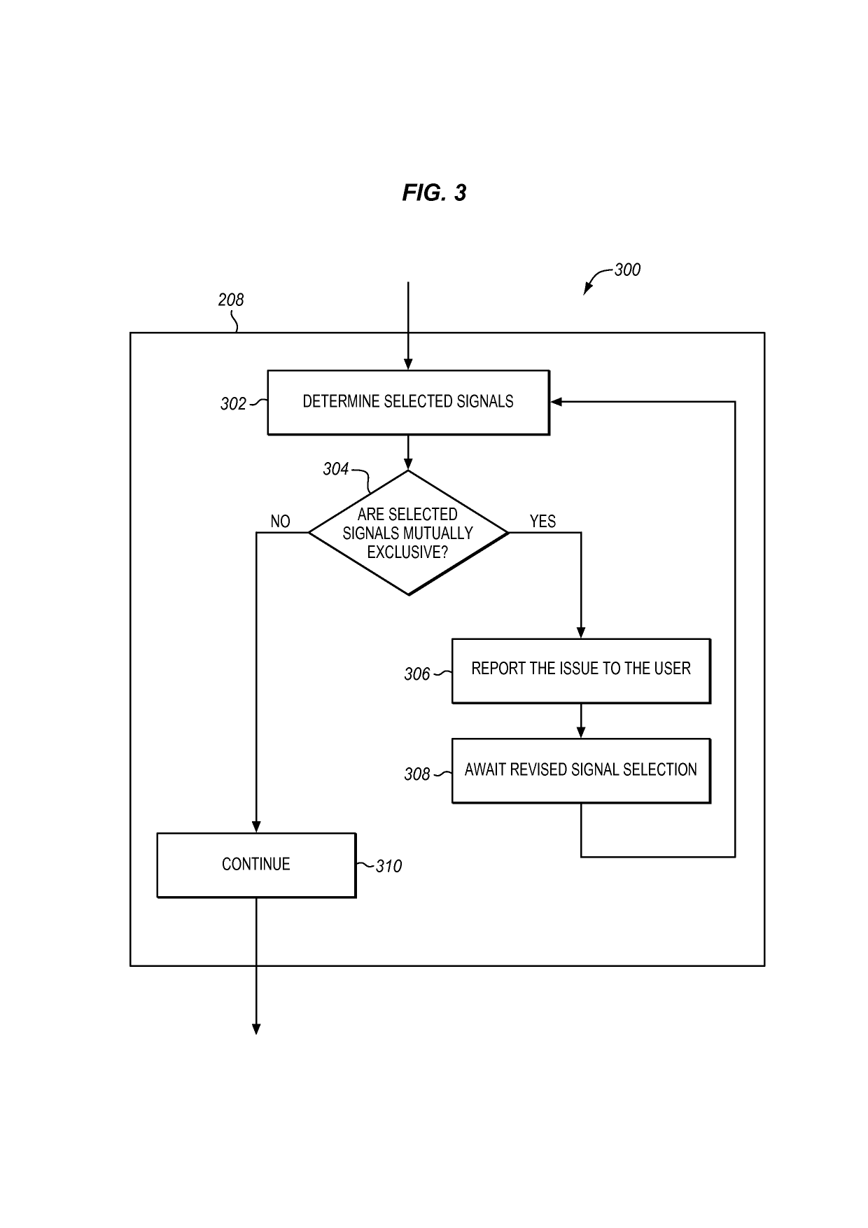

FIG. 3 is a flowchart describing exemplary further details of selecting internal signals of a circuit for acquisition in accordance with features and aspects hereof. Specifically, method 300 of FIG. 3 illustrates further features of step 208, wherein internal operational signals of a circuit are selected for acquisition.

Step 302 includes determining the selected signals. For example, a user may provide a request for selection via a user interface. From this request, the identity of each selected signal may be acquired.

Step 304 includes determining whether two or more selected signals will utilize mutually exclusive configurations of the test registers of the test MUXs of the circuit to generate output signals. In short, if signals are selected which use conflicting register settings, the signals cannot be provided together. This determination may be made, for example, by comparing a set of test register values for test MUXs for one signal with a similar set for another signal. If each of the sets requires a different setting for the same register at some point along the hierarchy, the signals may be considered conflicting (i.e., the test logic of the circuit is not capable of providing both of these signals at the same time as test outputs). If there is a conflict, the method proceeds onward to step 306. Alternatively, if no conflict is detected, then processing continues onward to step 310, wherein the method continues onward to further steps of method 200 of FIG. 2.

Step 306 includes reporting the issue to a user. For example, an error message may be generated and provided to the user, or a list of conflicting selected signals may be provided to the user. This list of conflicting signals may be sorted into groups of signals that share the same conflicting register. Thus, each set of conflicts may be reported to the user for resolution. Step 308 includes awaiting a revised signal selection. Once a revised signal selection is made, the method returns to step 302, where the method determines the selected signals.

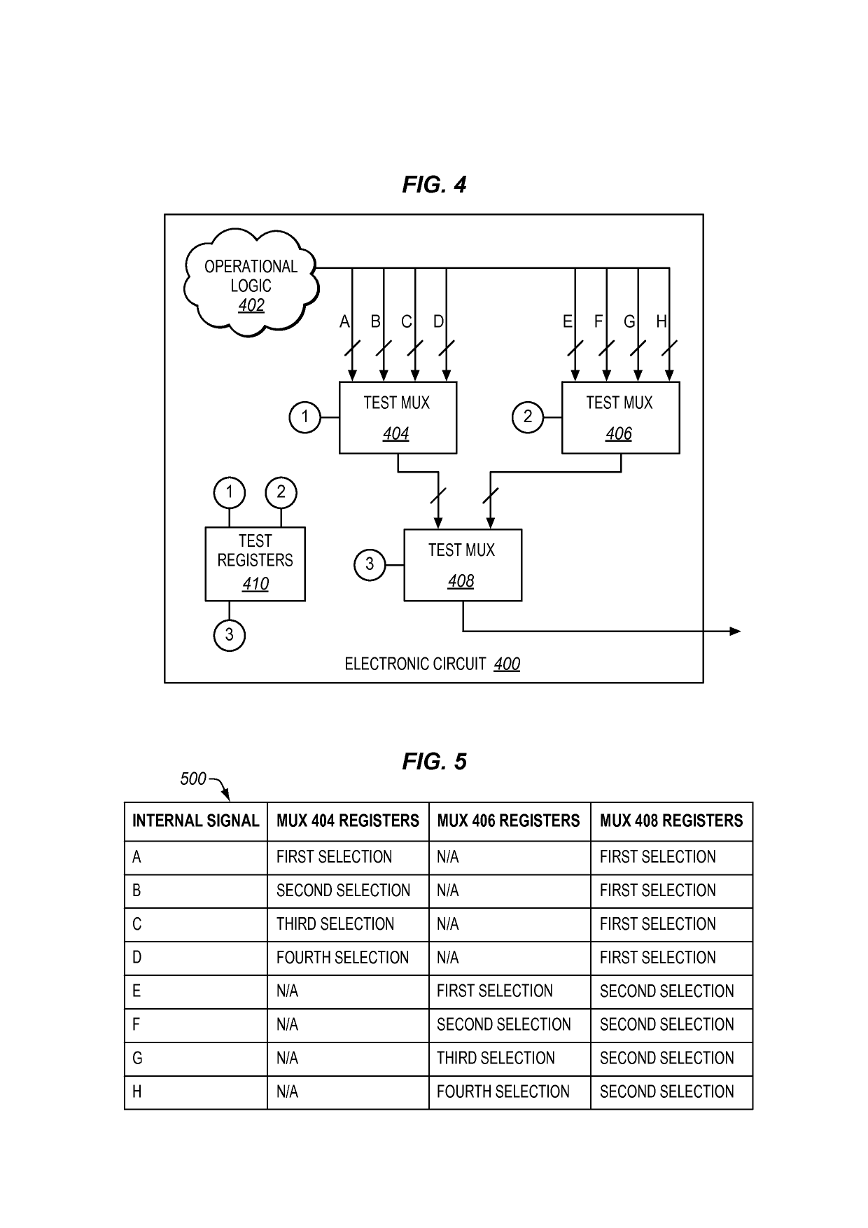

FIGS. 4-5 described below are diagrams illustrating a specific exemplary application circuit implementing test logic, and further illustrating a specific MUX mapping structure for that circuit. FIG. 4 is a block diagram of an exemplary circuit 400 in accordance with features and aspects hereof According to FIG. 4 circuit 400 includes operational logic 402 for performing tasks (e.g., the logic for performing the primary functions of circuit 400). Operational logic 402 includes eight signals, (A through H) which are provided to test MUXs 404-408. Test MUXs 404-408 route signals downstream based upon selection signals that are provided via test registers 410. Test registers 410 are externally programmable. In this embodiment, test MUX 404 receives signals A-D, and test MUX 406 receives signals E-H. Test MUXs 404 and 406 are adapted to route received signals to an output, depending upon various programmed values of test registers 410. The outputs from test MUXs 404 and 406 are then fed into test MUX 408, which may then route the incoming signals to its own output.

FIG. 5 is a block diagram of an exemplary test MUX mapping structure 500 for circuit 400 of FIG. 4 in accordance with features and aspects hereof According to FIG. 5, each internal operational signal is listed in an entry along with a combination of hardware register settings that are used to program the test MUXs to apply the signal to an output of circuit 400. For example, according to mapping structure 500, to acquire signal A, registers for MUX 404 should be programmed according to a first selection. Note that the selection for the internal hardware registers (and indeed, even the number and type of internal hardware registers) may vary depending on the particular design used for test MUX 404. Mapping structure 500 further includes an indication that no register selection are used for MUX 406 to provide signal A as an output. However, mapping structure 500 does include an indication that registers for MUX 408 should be programmed according to their own first selection in order to provide signal A as an output. Note that the same register selection is used for MUX 408 to output each of signals A-D. This is because signals A-D correspond to the same input bus for MUX 408. Therefore, the same register selection value for MUX 408 will provide information from the same input bus as output for circuit 400—regardless of what specific signal is carried upon the input bus. Note that mapping structure 500 may be indexed by any number of criteria, and need not be indexed based upon a given selected signal. Mapping structure 500 may be stored in a memory accessible by a testing system, and may be implemented as one or more data structures in the memory.

In further embodiments (and depending upon the complexity of the test logic in a given circuit), combinations of register selections may be used to forwarding multiple selected signals along the same bus at the same time. For example, components of the test logic may allow a register selection for forwarding both signal A and signal B along the same bus to another test logic component (so long as the register selections do not conflict and the bus is capable of supporting both signals).

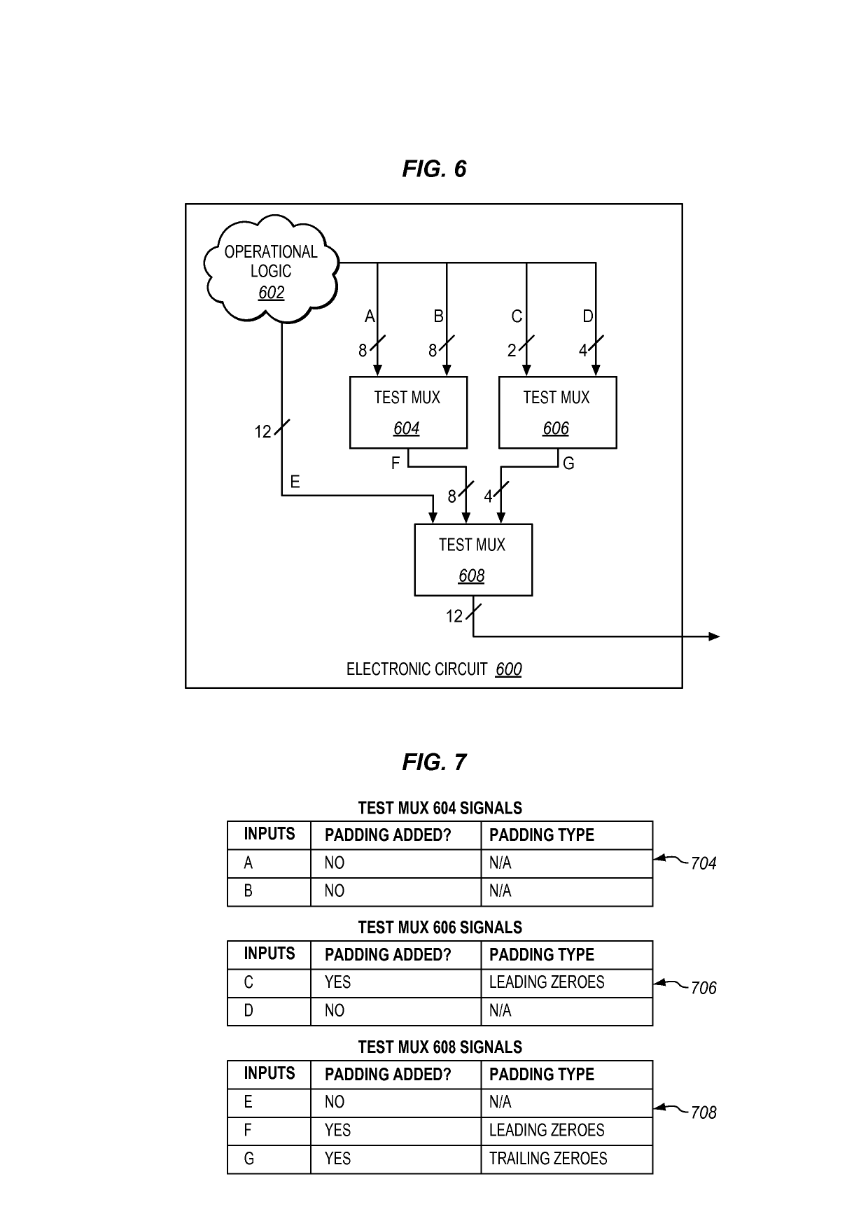

FIGS. 6-7 described below are diagrams illustrating a specific exemplary application circuit implementing test logic, and further illustrating a specific description of the signal padding applied by that circuit. FIG. 6 is a block diagram of another exemplary circuit 600 in accordance with features and aspects hereof According to this embodiment, operational logic 602 provides signals A-E to test MUXs 604-608. Specifically, test MUX 604 applies received input signals to an 8-bit wide output signal path, test MUX 606 applies received input signals to a 4-bit wide output signal path, and test MUX 608 applies received signals to a 12-bit wide output signal path. Test MUX 604 receives each of input signals A and B along an 8-bit wide bus, test MUX 606 receives input signal C along a 2-bit wide bus and input signal D along a 4-bit wide bus, and test MUX 608 receives input signal E along a 12-bit wide bus (test registers for circuit 600 have been omitted for purposes of simplification). In these situations, where signal size and bus size varies, certain signals may be padded with non-informational content and/or may have that content truncated as they travel across a test MUX hierarchy.

FIG. 7 is a block diagram of data structures 704-708 indicating whether internal operational signals of a circuit have been padded with non-informational content in accordance with features and aspects hereof. Data structure 704 corresponds to padding information for test MUX 604, data structure 706 corresponds to padding information for test MUX 606, and data structure 708 corresponds to padding information for test MUX 608. Data structures 704-708 may be stored in a memory accessible by a testing system, and may be implemented as one or more data structures in the memory.

The padding information may be determined by a testing system analyzing the RTL representation of circuit 600. For example, the RTL representation of the circuit may indicate the bus width for each input and output of the test MUX hierarchy, and signal padding and truncation information may be inferred from these changing bus widths. In another example, truncation may be determined based upon byte lane steering logic indicated in the RTL that masks off part of an input for a test MUX and applies another input for that byte lane. Padding may similarly be determined based upon logic described in the RTL information. Depending upon which signals have been selected for acquisition, non-selected signals may be considered padding by the testing system.

According to data structure 704, no padding is added to signals A and B before they are sent as output from test MUX 604. According to data structure 706, leading zeroes are added to signal C in order to transfer signal C from a two bit wide bus to a four bit wide bus at test MUX 606 (e.g., a representative signal C might be transformed from “11” to “0011”). Signal D however, because it is moved from a four bit bus to another four bit bus, does not need padding.

Note that inputs F and G (outputs of test MUXs 604 and 606) received along test MUX 608 may be padded from eight and four bit wide buses to a twelve bit wide output bus. Thus, these incoming signaling may need to be altered to conform with the wider bus structure. Therefore, inputs F (corresponding to signals A and B) and G (corresponding to signals C and D) are padded to make them compatible with the wider bus. F has leading zeroes added, and G has trailing zeroes added. Thus, if an original signal C was “11,” and was transformed by test MUX 606 to “0011,” it would be further transformed by test MUX 608 to become “001100000000.” Understanding how signals are padded by the various test MUXs may be important when it comes to interpreting a received signal provided as output. Without an understanding of how and where padding was added in the test logic, it would be hard, if not impossible to determine from the output signal “001100000000” whether the original signal C was “00,” “01,” “10,” or “11.”

In some embodiments, the padding may comprise leading or trailing zeroes (i.e., extra signals coupled to a logic “0”), leading or trailing ones (i.e., extra signals coupled to a logic “1”), leading or trailing random information (i.e., extra signals coupled to a floating logic value), or any sort of non-informational content combined with the received signals. Similar operations may be performed for truncation if a signal is moved from a larger bus size to a smaller bus size. Depending on whether information (and/or padding) is truncated at the leading end or the trailing end, it could change the perceived value of an internal operational signal.

While the invention has been illustrated and described in the drawings and foregoing description, such illustration and description is to be considered as exemplary and not restrictive in character. One embodiment of the invention and minor variants thereof have been shown and described. In particular, features shown and described as exemplary software or firmware embodiments may be equivalently implemented as customized logic circuits and vice versa. Protection is desired for all changes and modifications that come within the spirit of the invention. Those skilled in the art will appreciate variations of the above-described embodiments that fall within the scope of the invention. As a result, the invention is not limited to the specific examples and illustrations discussed above, but only by the following claims and their equivalents.

1. A method operable as programmed instructions on a computer system, the method comprising:
acquiring, by use of the computer system, a Register Transfer Level (RTL) representation of an electronic circuit, the circuit implementing operational logic for performing tasks, the circuit further implementing test logic that may be externally programmed for providing one or more output signals corresponding to internal operational signals;
analyzing, via the computer system, the RTL representation to identify test multiplexers (MUXs) having registers for implementing the test logic;
correlating, via the computer system, test register values for the test MUXs with outputs corresponding to the internal operational signals, based upon the RTL representation;
selecting a desired internal operational signal for acquisition; and
programming, via the computer system, the test registers of the test MUXs of the circuit based on the correlated test register values to acquire the selected internal operational signal and to apply the acquired signal as one or more output signals.

2. The method of claim 1, further comprising:
selecting multiple desired internal operational signals for acquisition; and
programming the test registers of the test MUXs of the circuit to acquire the selected internal operational signals and to apply the acquired signals as multiple output signals.

3. The method of claim 2, further comprising:
determining that two or more selected internal operational signals will utilize mutually exclusive configurations of the test registers of the test MUXs of the circuit to generate output signals; and
reporting the determination to a user.

4. The method of claim 1, wherein the step of correlating test register values for the test MUXs with outputs further comprises:
determining a test MUX hierarchy from the RTL representation, the test MUX hierarchy comprising a plurality of test MUXs and linking the inputs of test MUXs to outputs of other test MUXs;
tracing an internal operational signal through the test MUX hierarchy to an output signal; and
recording the combination of test register values for test MUXs of the test MUX hierarchy that correspond to applying the internal operational signal as one or more output signals.

5. The method of claim 1, further comprising:
determining a test MUX hierarchy from the RTL representation, the test MUX hierarchy comprising a plurality of test MUXs and linking the inputs of test MUXs to outputs of other test MUXs;
determining that an internal operational signal will enter an input of a test MUX as a first number of bits; and
determining that the internal operational signal will exit an output of the test MUX as a
second number of bits; wherein
programming the test registers is performed based upon how the internal operational
signal will be converted at the test MUX from the first number of bits to the second number of bits.

6. The method of claim 5, wherein the programming further comprises:
determining that the internal operational signal will be padded with non-informational content when defined by the second number of bits.

7. The method of claim 1, wherein:
the internal operational signals are used by the electronic circuit to perform the primary function of the electronic circuit.

8. A non-transitory computer readable medium embodying programmed instructions which, when executed by a processor, are operable for performing a method comprising:
acquiring a Register Transfer Level (RTL) representation of an electronic circuit, the circuit implementing operational logic for performing tasks, the circuit further implementing test logic that may be externally programmed for providing one or more output signals corresponding to internal operational signals;
analyzing the RTL representation to identify test multiplexers (MUXs) having registers for implementing the test logic;
correlating test register values for the test MUXs with outputs corresponding to the internal operational signals, based upon the RTL representation;
selecting a desired internal operational signal for acquisition; and
programming the test registers of the test MUXs of the circuit based on the correlated test register values to acquire the selected internal operational signal and to apply the acquired signal as one or more output signals.

9. The medium of claim 8, wherein the method further comprises:
selecting multiple desired internal operational signals for acquisition; and
programming the test registers of the test MUXs of the circuit to acquire the selected internal operational signals and to apply the acquired signals as multiple output signals.

10. The medium of claim 9, wherein the method further comprises:
determining that two or more selected internal operational signals will utilize mutually exclusive configurations of the test registers of the test MUXs of the circuit to generate output signals; and
reporting the determination to a user.

11. The medium of claim 8, wherein the step of correlating test register values for the test MUXs with outputs further comprises:
determining a test MUX hierarchy from the RTL representation, the test MUX hierarchy comprising a plurality of test MUXs and linking the inputs of test MUXs to outputs of other test MUXs;
tracing an internal operational signal through the test MUX hierarchy to an output signal; and
recording the combination of test register values for test MUXs of the test MUX hierarchy that correspond to applying the internal operational signal as one or more output signals.

12. The medium of claim 8, the method further comprising:
determining a test MUX hierarchy from the RTL representation, the test MUX hierarchy comprising a plurality of test MUXs and linking the inputs of test MUXs to outputs of other test MUXs;
determining that an internal operational signal will enter an input of a test MUX as a first number of bits; and
determining that the internal operational signal will exit an output of the test MUX as a
second number of bits; wherein programming the test registers is performed based upon how the internal operational
signal will be converted at the test MUX from the first number of bits to the second number of bits.

13. The medium of claim 12, wherein the programming further comprises:
determining that the internal operational signal will be padded with non-informational content when defined by the second number of bits.

14. The medium of claim 12, wherein the programming further comprises:
determining that the internal operational signal will be truncated when defined by the second number of bits.

15. A circuit testing system comprising:
a control unit adapted to acquire a Register Transfer Level (RTL) representation of an electronic circuit, the circuit implementing operational logic for performing tasks, the circuit further implementing test logic that is externally programmable for providing one or more output signals corresponding to internal operational signals, wherein
the control unit is further adapted to analyze the RTL representation to identify test multiplexers (MUXs) having registers for implementing the test logic, and adapted to correlate test register values for the test MUXs with outputs corresponding to the internal operational signals, based upon the RTL representation;
a user interface adapted to enable a user to select a desired internal operational signal for acquisition; and
a circuit interface adapted to program the test registers of the test MUXs of the circuit based on the correlated test register values to acquire the selected internal operational signal and to apply the acquired signal as one or more output signals.

16. The circuit testing system of claim 15, wherein:
the user interface is further adapted to enable a user to select multiple desired internal operational signals for acquisition; and
the circuit interface is further adapted to program the test registers of the test MUXs of the circuit to acquire the selected internal operational signals and to apply the acquired signals as multiple output signals.

17. The circuit testing system of claim 16, wherein:
the control unit is further adapted to determine that two or more selected internal operational signals will utilize mutually exclusive configurations of the test registers of the test MUXs of the circuit to generate output signals; and
the user interface is further adapted to report the determination to a user.

18. The circuit testing system of claim 15, wherein the control unit is adapted to correlate test register values for the test MUXs with outputs by:
determining a test MUX hierarchy from the RTL representation, the test MUX hierarchy comprising a plurality of test MUXs and linking the inputs of test MUXs to outputs of other test MUXs;
tracing an internal operational signal through the test MUX hierarchy to an output signal; and
recording the combination of test register values for test MUXs of the test MUX hierarchy that correspond to applying the internal operational signal as one or more output signals.

19. The circuit testing system of claim 15, wherein:
the control unit is further adapted to determine a test MUX hierarchy from the RTL representation, the test MUX hierarchy comprising a plurality of test MUXs and linking the inputs of test MUXs to outputs of other test MUXs, adapted to determine that an internal operational signal will enter an input of a test MUX as a first number of bits, and adapted to determine that the internal operational signal will exit an output of the test MUX as a second number of bits, wherein
the control unit is further adapted to program the test registers based upon how the internal operational signal will be converted at the test MUX from the first number of bits to the second number of bits.

20. The circuit testing system of claim 19, wherein
the control unit is further adapted to determine that the internal operational signal will be padded with non-informational content when defined by the second number of bits, and to program the test registers based upon the determination.
